(19) United States
(12) Patent Application Publication
(10) Pub. No.: US 2004/0027553 A1
(43) Pub. Date: Feb. 12, 2004

(54) Method for the characterization of an illumination source in an exposure apparatus

(76) Inventors: Wolfgang Henke, Radebeul (DE); Gerhard Kunkel, Radebeul (DE)

Correspondence Address: LERNER AND GREENBERG, P.A., POST OFFICE BOX 2480, HOLLYWOOD, FL, 33022-2480, US

(21) Appl. No.: 10/637,193

(22) Filed: Aug. 8, 2003

(30) Foreign Application Priority Data
Aug. 8, 2002 (DE) 102 36 422.2

(51) Int. Cl. G03B 27/32; G03F 1/00; G03B 27/54; G01B 11/02; G01J 1/00

(52) U.S. Cl. 355/77; 430/5; 355/67; 356/509; 356/511; 356/123

(57) ABSTRACT

A mask having at least one pair of mutually parallel slit structures, separated from one another by a distance in an opaque layer, is introduced into a mask mount. The mask side having the layer is turned to the illumination source. During mask exposure, a far field interference pattern is produced on the opposite rear side of the mask through the slit structures and projected into the substrate plane through a lens system of the exposure apparatus. The interference pattern is recorded as an image signal through exposure of a photosensitive layer of a wafer or by sensors on a movable substrate holder. Through determination of the contrast and subsequent Fourier transformation thereof as a function of distance between slits, the light distribution of the illumination can be derived. An advantageous mask has a multiplicity of slit structure pairs disposed with different angles with respect to a preferred direction and different distances in matrix form thereon.

### BACKGROUND OF THE INVENTION

1. Field of the Invention

The present invention relates to a method for the characterization of an illumination source in an exposure apparatus that includes the illumination source, a mask mount, an optical lens system, and a substrate plane. The invention relates, in particular, to a method for determining a light source distribution of the illumination source in the exposure apparatus.

In the field of semiconductor fabrication, structures are implemented on substrates with the aid of exposure of photosensitive layers on the substrates in an exposure apparatus. The substrates may be, by way of example, semiconductor wafers, masks or flat panels, etc. After a development step has been carried out, the exposed structures are, generally, transferred into the substrate in an etching step. Because it is often the case that the highest possible structure densities are to be obtained, in these steps, the production of structures with the smallest possible structure width represents a major challenge.

Associated with a similar problem area is the aim of achieving the highest possible positional accuracies of the various structure planes of a circuit relative to one another. Recently, an error contribution originating from the exposure apparatuses, in particular, the illumination sources and lens systems thereof, has become more and more evident. It is caused by the fact that the further development of high-quality lens systems can scarcely keep pace with that of the process technology for the accuracy of structure formation.

Errors in the region of the illumination source or the lens system have an effect particularly when the various structure planes on a substrate are produced progressively in different exposure apparatuses. However, error contributions also often arise when in each case different illumination settings of the lens system, of the apertures, or of the illumination sources are used for different structure planes of one and the same substrate.

Therefore, it is the case, nowadays, that increasingly a transition is being made to carrying out a characterization of illumination sources and their lens systems to be able to estimate the expected error during the projection of a structure from a mask onto a substrate depending on the illumination settings or the structure that is currently to be projected, or to carry out the adjustment or calibration of the projection optics in accordance with the requirements.

The effects resulting from inadequacies of an illumination source are, inter alia: variations due to focus-dependent magnification, focus-dictated lateral displacements, varying printability of structures that have a structure width close to the resolution limit of the system, depending on the structure design, or a varying illumination intensity transversely over the exposure field, i.e., the presence of gradients. The properties determined by characterization are compared between different apparatuses to be able to select therefrom, by way of example, a next exposure apparatus to be used for projecting a structure plane onto a substrate.

In such a case, considerable differences may arise, in particular, between groups of exposure apparatuses supplied by different manufacturers so that the characterization results may already be significant in the context of planning a fabrication installation.

In the further development of new lithography techniques, too, the condition of an illumination source respectively considered plays a considerable part so that the characterization results may, advantageously, be used as input data for simulations of lithography processes.

Hitherto, for characterization of an illumination source, series of exposures have been carried out on a substrate. The lens system has been set such that the illumination source has been imaged directly onto the substrate. Series of exposure fields have been generated in this case, a different value of the exposure dose of the illumination source having been used for each exposure field with the respective image of the illumination source. The developed structures have been measured and evaluated in an inspection apparatus, for instance, an optical microscope or a scanning electron microscope. However, such a procedure entails the disadvantage that follow-up processes that are necessarily carried out between the steps of exposure and measurement may have an erroneous influence on the measurement result. Moreover, the calibration methods, for instance a method disclosed in U.S. Pat. No. 6,356,345 B1 to McArthur et al., in which a measured line profile is assigned to a local exposure intensity, by way of example, are complicated and, in some instances, exhibit errors.

### SUMMARY OF THE INVENTION

It is accordingly an object of the invention to provide a method for the characterization of an illumination source in an exposure apparatus that overcomes the hereinafore-mentioned disadvantages of the heretofore-known devices and methods of this general type and in which the quality of the characterization is increased and external influences not connected with the illumination source are largely reduced and that reduces the outlay for carrying out characterization of an illumination source or a lens system.

With the foregoing and other objects in view, there is provided, in accordance with the invention, a method for characterizing an illumination source in an exposure apparatus, including the steps of providing the exposure apparatus with the illumination source, a mask mount, an optical lens system, and a substrate plane, providing a mask with a first side, on which an opaque layer is disposed, and an opposite second side having a surface, at least two mutually parallel slits separated from one another by a distance being disposed in the opaque layer, introducing the mask into the mask mount with the first side having the opaque layer facing the illumination source, illuminating the opaque layer with the illumination source to form an interference pattern of the slits on the surface of the second side of the mask, imaging the interference pattern formed on the second side of the mask into the substrate plane through the optical lens system, and recording an image signal from the imaged interference pattern in the substrate plane, the image signal representing a light distribution of the illumination source for a characterization of the illumination source.

According to the present invention, an illumination source is understood to be both the light-generating element, for instance, a laser or a halogen lamp, etc., and the light-generating element together with that part of the lens system that is disposed upstream of the location of the mask mount in the beam path of the exposure apparatus. That part of the lens system that is disposed upstream of the mask mount in the beam path as seen from the exposure source includes apertures and diaphragms for defining the illumination setting, thus, for instance, for setting an annular illumination. It also includes the so-called condenser lenses for collimating the light beams for the formation of a substantially parallel beam pencil that falls onto a mask disposed in the mask mount.

The invention provides a particular mask having an opaque layer on a front side, at least one double slit being disposed in the layer. The opaque layer lies on a transparent carrier material of the mask. The double slit, thus, enables beams to pass through the slit and the transparent carrier material of the mask. The double slit can be two slits parallel to one another. The mask may also have a plurality of double slit pairs of different size and orientation on the mask surface.

The mask, which may also be embodied as a reticle for demagnifying imaging, has a front side and a rear side. Here, the front side denotes that side on which the opaque layer with the double slit structure formed therein is disposed. It is possible for further transparent or semitransparent layers to be disposed on the front or rear side. For the present description, it is assumed in representative fashion that the rear side is formed by the surface of the transparent glass carrier material. In the case of a semitransparent or transparent layer formed thereon, the surface thereof could also be assumed to be the surface of the rear side.

In a configuration with the optical lens system and the substrate plane, the mask mount in the exposure apparatus has the property that the rear side of a mask introduced into it leads to a sharp imaging in the substrate plane during an exposure through the optical lens system. Therefore, during a conventional exposure, the front side of the mask is turned toward the underside of the mask mount. This means that, in accordance with the prior art, the rear side with the surface of the transparent glass carrier substrate is turned toward the light source in the beam path.

According to the present invention, by contrast, the mask described including the at least one double slit is clamped into the mask mount with the front side in the direction toward the illumination source. The rear side of the mask is, now, situated in that position in which a structure formed on it is imaged with sharp contrast into the substrate plane, that is to say, on the underside of the mask mount. The distance between the front side and this position corresponds to the thickness of the mask or the glass carrier material, which amounts to about 6000 μm, for example, in the case of masks used nowadays.

As the next step, the exposure source is switched on, thereby illuminating the opaque layer and the double slit formed therein. On account of the double slit, a so-called far field interference pattern forms on the rear side of the mask, that is to say, on the surface of the glass carrier material. The far field interference pattern is sharply imaged into the substrate plane by the optical lens system. An image signal of the interference pattern is recorded at the substrate plane, which can be carried out in different ways in accordance with at least two advantageous refinements.

The recorded interference pattern has a form that depends on the extent of the illumination source, the exposure wavelength and the distance between the two slits of the double slit. If the exposure wavelength and the double slit distance are known, then the extent and brightness distribution of the illumination source can, accordingly, be derived from the form of the interference pattern.

The procedure for determining the extent of an illumination source from a recorded image signal of an interference pattern is known in the literature, for example, as Young's double slit experiment. The procedure will be explained in more detail below with reference to the drawings.

In accordance with one advantageous refinement, a semiconductor wafer coated with a photosensitive resist records the image in the substrate plane. The recorded interference pattern can, subsequently, be examined in an inspection apparatus, in which case the resulting lines of the interference pattern can be measured in respect of their width. If a scanning electron microscope (SEM) is used, then it is also possible to determine a three-dimensional line profile that corresponds to the local intensity of the interference pattern on the exposed semiconductor wafer.

In accordance with a further refinement, it is possible to use sensors provided on the substrate holder in the substrate plane to measure the local intensities of the interference pattern in the substrate plane. For such a purpose, the substrate holder is, advantageously, moved horizontally within the substrate plane such that the sensor is passed through the interference pattern. In such a case, the respective intensity is measured in a manner dependent on the position of the substrate holder or the sensor, thereby producing a profile of the interference pattern.

In accordance with another mode of the invention, there are provided the steps of determining a contrast by determining a maximum value and a minimum value of an intensity of the interference pattern from the recorded image signal, calculating a contrast function from the distance between the slits and the determined contrast, and determining the light distribution of the illumination source by calculating a Fourier transform from the contrast function.

In accordance with a further mode of the invention, the recording of the image signal is carried out by exposing a photosensitive resist on a substrate in the substrate plane, subsequently developing the substrate to remove exposed portions of resist, and subsequently measuring a height profile of unexposed portions of the resist with a microscope.

In accordance with an added mode of the invention, the recording of the image signal is carried out with a sensor moved in the substrate plane.

In accordance with an additional mode of the invention, the illumination source is provide as a further optical lens system and/or a mirror system.

In accordance with yet another mode of the invention, a wavelength of light emitted by the illumination source is determined and the step of providing the mask is carried out by selecting a thickness between the opaque layer on the first side and the surface on the second side of the mask, and/or a respective width of the mutually parallel slit structures to make a quotient of twice the square of the width and the thickness be less than the wavelength.

In accordance with yet a further mode of the invention, a numerical aperture of a diaphragm of the optical lens system is determined and the mask is provided by selecting a thickness between the opaque layer on the first side and the surface on the second side of the mask and/or the distance by which the mutually parallel slit structures are separated from one another to make a quotient of the distance and the thickness be less than the numerical aperture.

With the objects of the invention in view, there is also provided a method for characterizing an illumination source in an exposure apparatus, including the steps of providing a mask with a first side, on which an opaque layer is disposed, and an opposite second side having a surface, and disposing at least two mutually parallel slits separated from one another by a distance in the opaque layer, introducing the mask into a mask mount of the exposure apparatus with the first side having the opaque layer facing the illumination source, illuminating the opaque layer with the illumination source to form an interference pattern of the at least two mutually parallel slits on the surface of the second side of the mask, imaging the interference pattern formed on the second side of the mask into the substrate plane of the exposure apparatus through an optical lens system of the exposure apparatus, and recording an image signal from the imaged interference pattern in the substrate plane, the image signal representing a light distribution of the illumination source for a characterization of the illumination source.

With the objects of the invention in view, there is also provided a mask for characterizing an illumination source, including a transparent carrier material and an opaque layer disposed at the transparent carrier material and having a first pair of two mutually parallel slits separated from one another by a first distance and disposed in the opaque layer and a second pair of mutually parallel slits separated from one another by a second distance and disposed in the opaque layer, the second distance being greater than the first distance.

In accordance with yet an added feature of the invention, the opaque layer has a third pair of mutually parallel slits separated from one another by the first distance and disposed in the opaque layer, the slits of the first pair having a longitudinal side with a first orientation in the opaque layer, the slits of the second pair having a longitudinal side with a second orientation in the opaque layer, the first and second orientations forming an angle.

In accordance with yet an additional feature of the invention, the opaque layer has a third pair of mutually parallel slits separated from one another by the first distance and disposed in the opaque layer, the slits of the first pair having a longitudinal side with a first orientation in the opaque layer, the slits of the second pair having a longitudinal side with a second orientation in the opaque layer at an angle to the first orientation.

In accordance with a concomitant feature of the invention, the opaque layer has a matrix configuration of a multiplicity of pairs of slits formed parallel to one another respectively, the matrix having rows and columns, the slits of the respective pairs being separated from one another by a number of different distances and having longitudinal sides with a number of different orientations in the opaque layer, and each pair of the mutually parallel slits in a row of the matrix has precisely one value of the number of different distances of the slits and in a column of the matrix has precisely one angle of the number of different orientations of the longitudinal sides of the slits.

Other features that are considered as characteristic for the invention are set forth in the appended claims.

Although the invention is illustrated and described herein as embodied in a method for the characterization of an illumination source in an exposure apparatus, it is, nevertheless, not intended to be limited to the details shown because various modifications and structural changes may be made therein without departing from the spirit of the invention and within the scope and range of equivalents of the claims.

The construction and method of operation of the invention, however, together with additional objects and advantages thereof, will be best understood from the following description of specific embodiments when read in connection with the accompanying drawings.

### BRIEF DESCRIPTION OF THE DRAWINGS

FIG. 1 is a diagrammatic cross-sectional illustration of the construction of an exposure apparatus with exposure source, condenser lens, mask rotated according to the invention, objective lens, and substrate plane;

FIG. 2 is a diagrammatic perspective view of a formation of an interference pattern from a double slit according to the invention;

FIG. 3 is a cross-sectional view through the mask according to the invention;

FIG. 4 is a graph indicating a profile of an interference pattern that forms on the rear side of the mask according to the invention;

FIG. 5 are diagrammatic illustrations of the formation of interference patterns according to the invention in the substrate plane for three double slits having different slit distances in each case;

FIG. 6 is a graph illustrating the coherence function (contrast) determined as a function of the slit distance according to the invention;

FIG. 7 is a fragmentary diagrammatic illustration of a mask according to the invention with double slit structures having a different slit distances and orientations;

FIG. 8 is a graph illustrating a simulation of coherence functions and a comparison with a theoretical curve according to the invention;

FIG. 9 is a diagrammatic perspective view of an exemplary embodiment according to the invention for determining the telecentricity of an illumination source; and

FIG. 10 is a graph illustrating an approximately linear relationship between lateral displacement caused by a telecentricity during an imaging onto a substrate according to the invention as a function of the inclination of the exposure source with respect to the optical axis of the lens system.

### DESCRIPTION OF THE PREFERRED EMBODIMENTS

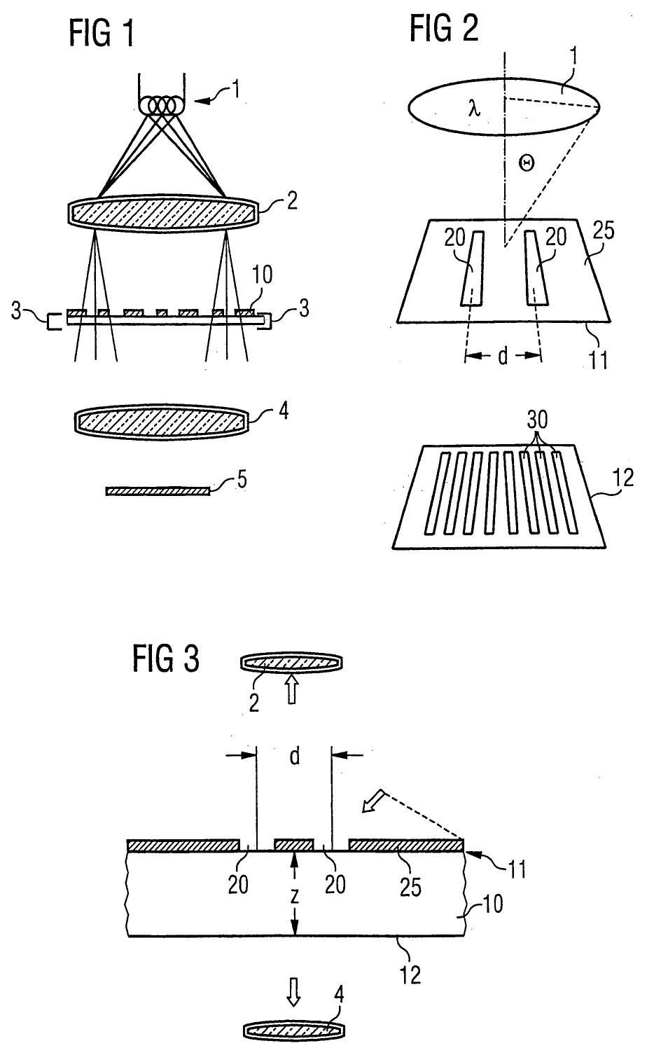

Referring now to the figures of the drawings in detail and first, particularly to FIGS. 1 and 2 thereof, there is shown a configuration according to the invention with an exposure or illumination source 1 having an extent θ, a condenser lens 2, a mask mount 3, in which a rotated mask 10 is disposed, an objective lens 4, and a substrate plane 5. The mask 10 is rotated to the effect that double slit structures 20 formed in an opaque layer 25 on the front side 11 of the mask 10 face the condenser lens 2 and the illumination source 1. The rear side 12 of the mask 10 is sharply imaged into the substrate plane 5 through the positioning of the mask mount 3, in which the mask 10 is clamped, relative to the objective lens system 4 and the substrate plane 5.

The diagrammatic illustration of FIG. 2 shows the resulting interference pattern 30 in the substrate plane 5. The illumination source 1 emits light of wavelength λ that, through the double slits with the slit distance d, leads to an interference pattern 30 on the rear side of the mask 10.

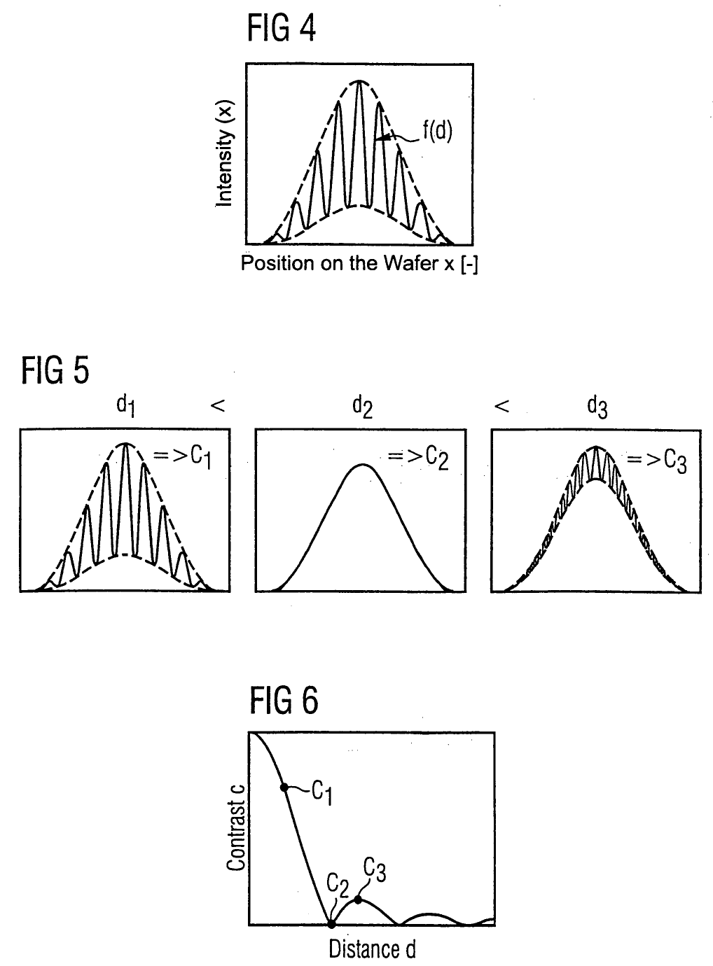

A section through the mask is illustrated in FIG. 3. The mask 10 has a thickness z of 6300 μm. The interference pattern 30 on the rear side of the glass carrier substrate of the mask 10 is imaged through the objective lens system 4 into the substrate plane 5, where movable sensors scan the pattern 30. A signal that typically occurs is illustrated in FIG. 4, where the intensity measured with the aid of the sensors is plotted against the position on the wafer. In such a case, the interference pattern is reproduced with a resolution of 150 nm by the sensors. This limit corresponds to the sensors that are already used nowadays on substrate holders from various manufacturers, but which are, generally, used for the adjustment of the substrate holder.

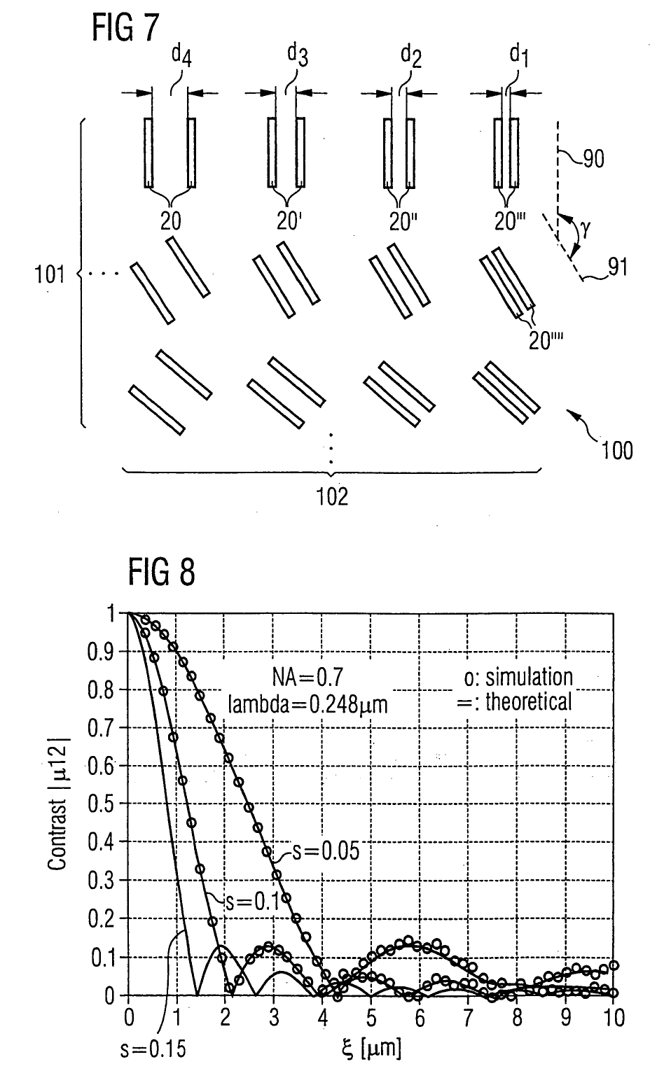

A mask 10 as illustrated in FIG. 7 is used in the exemplary embodiment. This mask has a plurality of double slit structures 20, 20′, 20″, 20′″. The latter differ by virtue of slit distances d1, d2, d3, etc. of respectively different magnitude.

Through the mask 10 illustrated in FIG. 7, a plurality of slit structures are converted into interference patterns 30 on the rear side 12 of the mask 10. The image signals of the projected interference patterns 30 recorded in the substrate plane 5 are illustrated for three of the slit structures in FIG. 5. Because only precisely one mask was used, the illumination conditions, i.e., the extent θ of the exposure source and the lens settings for the slit structures, are identical in each case. The variation of the slit distance leads to a different interference pattern, as can be seen in FIG. 5. The interference pattern is used to determine a contrast c1, c2, c3, which is also called coherence function. The contrast c, where:

$$c = \frac{{I}_{max} - {I}_{min}}{{I}_{max} + {I}_{min}} ,$$

represents the difference between the maximum and the minimum of the interference function determined for a given wafer position.

The contrast thus determined is plotted as a function of the slit distance d in FIG. 6. The function corresponds to the mathematical slit function. It has zero points, i.e., a vanishing contrast results for specific double slit distances d. In accordance with the exemplary embodiment, the contrast is determined given a known double slit distance and known wavelength of the illumination source, for which purpose setting up just one double slit on the mask already suffices according to the invention. To avoid scattering errors, however, it is expedient to use the mask 10 illustrated in FIG. 7 with different double slit distances d1-d4 for a multiplicity of double slit structures 20-20′″.

As the next step, the coherence function or the contrast illustrated in FIG. 6 as a function of the double slit distance d is subjected to a Fourier transformation so that a spatial distribution of the illumination source is determined therefrom using the Van Cittert-Zernike Theorems. The term “spatial” is to be understood here to mean that a direction-dependent brightness distribution I(φ, θ) is involved.

FIG. 8 shows the result of a simulation for various slit sizes or widths s, a numerical aperture of 0.7 with a wavelength of 248 nm having been used as settings of the illumination source. The solid lines show the theoretical curve that results from the geometrical relationships in accordance with FIG. 6, and also as circles of the simulation results for the projection of an interference pattern 30 of double slit structures as can be seen in FIG. 7.

To actually be able to obtain a far field interference structure, the slit structures 20 of the double slits have to be smaller than a specific limit value. Otherwise, the result would simply be just a projection of the slit opening onto the rear side 12 of the mask 10. The condition reads as follows:

λ·z>2·s².

The numerical aperture of the projection lens also has a lower limit value above which a projection of the interference pattern can, advantageously, be implemented:

NA>d/z.

Complying with these two conditions, in particular, taking account of a large distance with respect to these limit values, leads to particularly advantageous measurement results with high quality.

FIG. 7 shows the configuration for complete measurement of the source. By virtue of a configuration turned by an angle γ, by further double slits 20″″, the illumination source 1 is measured in further directions in respect of its light distribution. The matrix illustrated in FIG. 7, thus, makes it possible to determine the spatial brightness distribution of the light source.

The interference pattern not only represents the absolute extent of the illumination source 1, but, rather, also the extent θ of contour lines of given intensity of the source. Therefore, gradients within the light distribution can also be determined by the Fourier transformation.

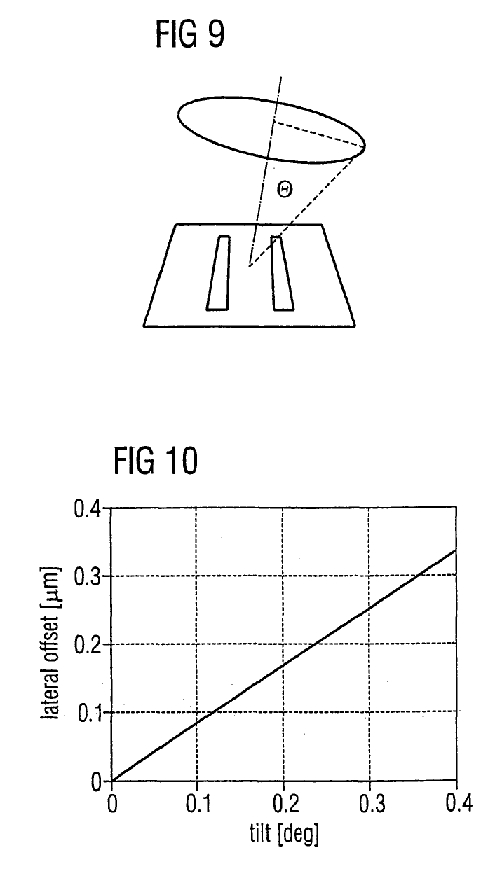

In a further exemplary embodiment, the method according to the invention is used to determine the telecentricity of the illumination source. As can be seen in FIG. 9, in illumination sources it is possible for the radiation direction of the illumination source to become inclined or off-center with respect to the optical axis of the lens system. This off-center disposition of the illumination source leads to a lateral displacement of the interference pattern on the rear side 12 of the mask 10. However, this only applies to interference patterns of double slit structures 20 having particularly small slit distances d. Slit structures 20 having particularly small slit distances d bring about a particularly wide interference pattern 30.

In such a case, there is picked out from the interference pattern 30 a position of those interference lines whose intensity in the substrate plane 5 is the highest for the entire interference pattern 30. This position is to be compared with the position of the double slits. This reference position of the double slits can be transferred into the substrate plane in various ways—in the exemplary embodiment, for instance, by a procedure in which, in a double exposure, in a further step using a first, non-rotated mask, reference marks in a vicinity of the double slit structures 20 are first imaged into the substrate plane 5. Only afterward is use made of the mask with the double slits with the method according to the invention to form the far field interference pattern 30.

FIG. 10 shows that it is only for small angles of inclination of the radiation direction of the illumination source 1 with respect to the optical axis that a linear relationship leads to the lateral displacement on the semiconductor substrate. A numerical aperture of 0.7 and σ=0.1 was used in the example. The exposure wavelength λ is 248 nm and the defocus is 50 μm. The illustration shows a range of angles of inclination of between 0 and 0.4 mrad. An actual inclination of the exposure source of 10 mrad produces a lateral displacement of 0.5 μm in this connection. Given a thickness z of the mask 10 of 6300 μm, this would result in a lateral displacement of 6.3 μm per 1 mrad telecentricity. With a resolution limit of 150 nm of the sensors on the substrate holder in the substrate plane 5, therefore, a resolution of the angles of inclination of 10 μrad is technically practicable.

We claim:

1. A method for characterizing an illumination source in an exposure apparatus, which comprises:
providing the exposure apparatus with the illumination source, a mask mount, an optical lens system, and a substrate plane;
providing a mask with a first side, on which an opaque layer is disposed, and an opposite second side having a surface, at least two mutually parallel slits separated from one another by a distance being disposed in the opaque layer;
introducing the mask into the mask mount with the first side having the opaque layer facing the illumination source;
illuminating the opaque layer with the illumination source to form an interference pattern of the slits on the surface of the second side of the mask;
imaging the interference pattern formed on the second side of the mask into the substrate plane through the optical lens system; and
recording an image signal from the imaged interference pattern in the substrate plane, the image signal representing a light distribution of the illumination source for a characterization of the illumination source.

2. The method according to claim 1, which further comprises:
determining a contrast by determining a maximum value and a minimum value of an intensity of the interference pattern from the recorded image signal;
calculating a contrast function from the distance between the slits and the determined contrast; and
determining the light distribution of the illumination source by calculating a Fourier transform from the contrast function.

3. The method according to claim 1, which further comprises carrying out the recording of the image signal by:
exposing a photosensitive resist on a substrate in the substrate plane;
subsequently developing the substrate to remove exposed portions of resist; and
subsequently measuring a height profile of unexposed portions of the resist with a microscope.

4. The method according to claim 1, which further comprises carrying out the recording of the image signal with a sensor moved in the substrate plane.

5. The method according to claim 1, which further comprises providing the illumination source as at least one of a further optical lens system and a mirror system.

6. The method according to claim 1, which further comprises:
determing a wavelength of light emitted by the illumination source;
carrying out the step of providing the mask by selecting at least one of:
a thickness between the opaque layer on the first side and the surface on the second side of the mask; and
a respective width of the mutually parallel slit structures;
to make a quotient of twice the square of the width and the thickness be less than the wavelength.

7. The method according to claim 1, which further comprises:
determining a numerical aperture of a diaphragm of the optical lens system;
carrying out the step of providing a mask by selecting at least one of:
a thickness between the opaque layer on the first side and the surface on the second side of the mask; and
the distance by which the mutually parallel slit structures are separated from one another;
to make a quotient of the distance and the thickness be less than the numerical aperture.

8. A method for characterizing an illumination source in an exposure apparatus, which comprises:
providing a mask with a first side, on which an opaque layer is disposed, and an opposite second side having a surface, and disposing at least two mutually parallel slits separated from one another by a distance in the opaque layer;
introducing the mask into a mask mount of the exposure apparatus with the first side having the opaque layer facing the illumination source;
illuminating the opaque layer with the illumination source to form an interference pattern of the at least two mutually parallel slits on the surface of the second side of the mask;
imaging the interference pattern formed on the second side of the mask into the substrate plane of the exposure apparatus through an optical lens system of the exposure apparatus; and
recording an image signal from the imaged interference pattern in the substrate plane, the image signal representing a light distribution of the illumination source for a characterization of the illumination source.

9. A mask for characterizing an illumination source, comprising:
a transparent carrier material; and
an opaque layer disposed at said transparent carrier material and having:
a first pair of two mutually parallel slits separated from one another by a first distance and disposed in said opaque layer; and
a second pair of mutually parallel slits separated from one another by a second distance and disposed in said opaque layer, said second distance being greater than said first distance.

10. The mask according to claim 9, wherein said opaque layer has a third pair of mutually parallel slits separated from one another by said first distance and disposed in said opaque layer, said slits of said first pair having a longitudinal side with a first orientation in said opaque layer, said slits of said second pair having a longitudinal side with a second orientation in said opaque layer, said first and second orientations forming an angle.

11. The mask according to claim 9, wherein said opaque layer has a third pair of mutually parallel slits separated from one another by said first distance and disposed in said opaque layer, said slits of said first pair having a longitudinal side with a first orientation in said opaque layer, said slits of said second pair having a longitudinal side with a second orientation in said opaque layer at an angle to said first orientation.

12. The mask according to claim 9, wherein:
said opaque layer has a matrix configuration of a multiplicity of pairs of slits formed parallel to one another respectively, said matrix having rows and columns, said slits of said respective pairs:
being separated from one another by a number of different distances; and
having longitudinal sides with a number of different orientations in the opaque layer; and
each pair of said mutually parallel slits:
in a row of said matrix has precisely one value of said number of different distances of said slits; and
in a column of said matrix has precisely one angle of said number of different orientations of said longitudinal sides of said slits.
